(19) United States
(12) Patent Application Publication
(10) Pub. No.: US 2008/0199657 A1
(43) Pub. Date: Aug. 21, 2008

(54) SUPERHYDROPHILIC OR SUPERHYDROPHOBIC PRODUCT, PROCESS FOR PRODUCING IT AND USE OF THIS PRODUCT

(75) Inventors: Philippe Capron, Luzinay (FR); Marc Plissonnier, Eybens (FR); Isabelle Rougeaux, Meylan (FR); Guillaume Savelli, Saint Quentin (FR)

Correspondence Address: BURR & BROWN, PO BOX 7068, SYRACUSE, NY, 13261-7068, US

(73) Assignee: Commissariat A L'Energie Atomique, Paris (FR)

(21) Appl. No.: 12/108,743

(22) Filed: Apr. 24, 2008

Related U.S. Application Data
(63) Continuation of application No. PCT/FR2006/051063, filed on Oct. 19, 2006.

(30) Foreign Application Priority Data
Nov. 14, 2005 (FR) 05.53450

(51) Int. Cl. B32B 27/00; B32B 17/00; B32B 27/30; B32B 3/02; G11B 5/64; C23C 16/00; B05D 3/10; H05H 1/00; H05H 1/24

(52) U.S. Cl. 428/141; 428/336; 428/421; 428/447; 428/426; 428/522; 427/248.1; 427/535; 427/569; 427/307

(57) ABSTRACT

A product having superhydrophilic or superhydrophobic surface physical properties comprising a substrate coated on its surface with a structuring layer added on to the surface and with a film deposited on the layer. The film is continuous, and the physical properties of the surface are conferred by the nature of the film, the surface of the layer and the deposited film having roughnesses with nanometric-size dimensions.

### FIELD OF THE INVENTION

The present invention relates to the field of surface treatments for conferring self-cleaning, dirt-repellent, anti-condensation or sliding properties with regard to fluids such as water or air.

The present invention relates more particularly to a product, whereof the outer surface has a coating developing a superhydrophilic or superhydrophobic character. It also relates to a method for producing such a coating and also its use.

In the context of the present invention, superhydrophobic means the property of a surface whereon, a drop of water forms a high contact angle with the said surface, typically higher than 150°. By definition, the contact angle is a dihedral angle formed by two contiguous interfaces at their apparent intersection. In this case, the surface is qualified as “non-wetting” with regard to water. This property is commonly called the “lotus effect”.

Conversely, a superhydrophilic surface has a contact angle close to 0°, or even non-measurable, with water. In this case, the surface is qualified as “wetting” with regard to water.

The technical field of the invention may further be considered as that of materials called nanostructured materials.

### PRIOR ART

In general, hydrophilic or hydrophobic surfaces are obtained by depositing a selectively hydrophilic or hydrophobic film on a substrate having nanometric-sized roughnesses. In fact, the roughnesses of a surface confer its hydrophobic or hydrophilic properties. In consequence, they determine its water-repellency (aptitude to allow a liquid to flow) and its self-cleaning or anti-condensation properties. As shown by Wilhelm Barthlott, the lotus leaf constitutes an example of a surface whereof the water-repellency is due to numerous microspheres distributed over this surface.

The hydrophobic character of a surface having microroughnesses is characterized by a low surface wettability, and hence by a large contact angle, which is explained by the fact that the liquid rests exclusively on the apices of the roughnesses of this surface. Conversely, the hydrophilic character of a surface is characterized by a high wettability thereof, hence by a contact angle close to zero, which is explained by the fact that the liquid “matches” the roughnesses of this surface.

Thus, the hydrophilic or hydrophobic character is obtained by structuring or “texturing” a surface, that is, by creating small-sized roughnesses therein, and then by depositing a film of a hydrophilic or hydrophobic material on this surface. It is the film that confers its hydrophilic or hydrophobic character on the material. The textured surface is generally a relatively thin layer that is itself deposited on a substrate; it is this substrate that has the properties, in particular mechanical, suitable for its use in the context of the desired application.

Thus, patent application FR-A-2 829 406 describes a method for producing a self-cleaning, dirt-repellent and/or anti-condensation surface. The structuring, or texturing, that is the creation of roughnesses on the surface, is carried out conventionally either by photolithography or by evaporation of a metal through a mask. A film of hydrophilic or hydrophobic material is then deposited by electrografting on this previously textured surface.

While the method described in this document serves to produce a surface reproducing the hydrophobic properties of a lotus leaf, it nevertheless has certain drawbacks.

First, conventional texturing processes, such as photolithography or evaporation of a metal through a mask, lead to the formation of roughnesses having dimensions in the range of a few microns, at best a few hundred nanometres. With such rouglmesses, the material does not have the transparency to light required by numerous applications, because the excessively large roughnesses prevent a sufficient transmission of the light (visible).

Furthermore, the implementation of such processes requires numerous steps and several devices. Moreover, these steps cannot all be carried out in a single chamber. This is why these processes are lengthy and costly to implement.

Document FR-A-2 864 110 teaches a method for producing carbon nanotubes designed to constitute roughnesses, on which a hydrophobic polymer film is deposited, or comprising an additional step for functionalizing the textured surface. However, this method also has a drawback that limits its applications.

In fact, the production of the nanotubes requires a high temperature, generally about 600° C. In consequence, this process is unsuitable for treating heat-sensitive substrates, such as polymers. This accordingly limits the potential applications of the hydrophobic product produced by such a process to applications for which a “heat-resistant” substrate may be suitable.

The present invention proposes a method for producing a product whose outer surface has superhydrophobic or superhydrophilic properties, but which does not have the limitations and drawbacks of the prior art methods. The present invention also relates to a product produced by this method.

### SUMMARY OF THE INVENTION

The present invention has an application for coating any type of substrate, heat-sensitive or not. The method covered by the invention, which is simple to implement and relatively inexpensive, serves in particular to preserve a satisfactory transparency, particularly to visible light, of the treated surfaces. These surfaces have water-repellent, dirt-repellent and/or anti-condensation properties.

The present invention therefore relates firstly to a product having a surface physical property, in the present case superhydrophilic or superhydrophobic. This product comprises a substrate coated on its surface with a structuring layer added on to this surface and with a film deposited on this layer.

According to the invention:
the film is continuous;
the physical properties of the said surface are conferred by the nature of the film;
and the surface of the layer receiving the deposited film has nanometric-size roughnesses.

Thus, the resulting product is transparent to light in particular.

In other words, the product according to the invention has in succession a substrate, an intermediate layer and a functionalizing film. Since the layer and the film have nanometric-size roughnesses, the combination of the layer and the film is transparent. Moreover, the nature of the film combined with the structuring of the surface by the roughnesses confers the surface a physical property, that is selectively a superhydrophilic character or a superhydrophobic character.

According to an advantageous embodiment of the invention, the layer participating in the coating may comprise hydrogen combined in various proportions with silicon and/or carbon. These materials have the property of reacting heterogeneously to an etching.

In practice, the thickness of the layer may be between 50 nm and 300 nm and the said roughnesses may have dimensions smaller than 50 nm. In other words, the roughnesses have “peaks”, “valleys” and intervals of about 50 mn between these peaks and valleys. Such dimensions serve in fact to obtain a product having a transparency close to that of the substrate before treatment.

According to a particular embodiment of the invention, the film may consist of a compound selected from the group comprising fluorocarbon polymers and polysiloxanes. Such a film has a character suitable for making the product superhydrophobic.

According to another particular embodiment of the invention, the film may consist of a compound selected from the group comprising silicas, polyvinylpyrydines, polyvinylpyrrolidones, polyols, polyimines, modified polysiloxanes (for example by UV or plasma treatment under oxygen), molecules having a hydroxyl or carboxyl radical, in order to make the said product superhydrophilic.

According to a particular embodiment of the invention, at least one of the materials constituting the product may be heat-sensitive. In other words, the substrate, the layer and/or film is (are) thermoplastic or thermosetting, that is, they undergo a deformation or change in nature during a high temperature rise. Thus, the product may consist of plastics.

According to a particular embodiment of the invention, the substrate consists of glass or polymethylmethacrylate (PMMA). Such materials have such a transparency that the product may itself have a relatively high transparency.

Furthermore, the invention also relates to a method for producing a product having a superhydrophilic or superhydrophobic surface physical property, this product comprising a substrate. According to the invention, the method comprises the steps consisting in succession in:
adding a layer to the outer surface of the substrate;
generating roughnesses of the outer surface of the layer thus added on the substrate;
depositing on the surface of the layer thus structured a continuous film, whereof the nature confers on the coating thereby produced the desired superhydrophilic or superhydrophobic character;
   the roughnesses having nanometric-size dimensions, so that the coating has transparency properties.

In other words, the method covered by the invention comprises the deposition of an intermediate nanometric-size layer on a substrate, followed by the deposition of a nanometric-size film for functionalizing this layer. Since the layer and the film have nanometric-size roughnesses, the coating remains transparent. If in addition, the substrate is also transparent, a completely transparent product is obtained. Moreover, the nature of the film combined with the structuring of the surface by the roughnesses confer a specific surface physical property, that is, selectively a superhydrophilic character or a superhydrophobic character.

According to an advantageous embodiment of the present invention, all the steps of the method can be carried out in a Plasma Enhanced Chemical Vapour Deposition (PECVD) chamber. This simplifies the procedure and minimizes the equipment required, and hence the production costs and times.

In practice, the layer is prepared by vacuum deposition technologies. This serves to avoid the presence of impurities, such as dust, which constitute defects in the surface texture of the product, hence as many points with reduced performance.

According to an advantageous embodiment of the invention, the roughnesses are produced by plasma etching. In other words, to structure or texture the surface of the intermediate layer, it is “bombarded” by a plasma which preferably attacks some of its atoms and some of its structures, thereby generating nanoroughnesses.

In practice, the film can be deposited by a method selected from the group comprising plasma enhanced chemical vapour deposition, electronic grafting (electrografting) and the deposition of a polymer solution followed by an evaporation of the solvent from the solution. These various methods thereby serve to deposit a continuous film on the surface of the intermediate layer.

The present invention also relates to the use of a product as previously mentioned for an application requiring a transparent dirt-repellent or anti-condensation surface. Typically, this product consists of dirt-repellent home windows, dirt-repellent spectacle lenses, anti-condensation diving masks, dirt-repellent optics of lighting systems such as headlights, automobile or aircraft windows with a moisture-repellent inner side and a self-cleaning outer side, dirt-repellent solar panels, dirt-repellent sensors and measuring instruments such as Pitot tubes or temperature probes, dirt-repellent sanitary surfaces such as those of wash basins, showers, self-cleaning toilets, dirt-repellent surface antennas such as for a radar or satellite television, dirt-repellent decorative metal structures, miscellaneous dirt-repellent industrial surfaces such as those of slaughterhouses, butcher shops, pork butcher shops, hospitals, kitchens, dirt-repellent and anti-condensation aircraft wings, inside walls of fluid containers such as those of anti-condensation bottles for recovering 100% of the content.

Furthermore, the present invention relates to the use of a product as previously mentioned for an application requiring a transparent and sliding surface with regard to fluids. Such a surface consists, for example, of ski bases, aero-or hydrodynamic parts.

### EMBODIMENT OF THE INVENTION

A transparent substrate, in this case a plaque of glass or polymethylmethacrylate (PMMA), is placed flat on the plate of a Plasma Enhanced Chemical Vapour Deposition (PECVD) chamber.

This substrate has mechanical properties suitable for the use of the product to which it belongs, in a predefined application, as for example home glazing. In the context of the present invention, transparent means, as commonly accepted, transparent to visible light. Obviously, the substrate may simultaneously be transparent to other radiations, such as infrared.

According to one of the embodiments of the invention, all the steps of the method arc carried out in the same chamber. This serves to simplify the procedure and minimize the equipment required, and hence the production costs and times. Conversely, the prior art methods cannot be implemented in full in a single chamber and they therefore require more equipment and handling operations, with a commensurate increase in costs and risks of breakage or injury.

At a predefined distance, about 5 cm, from the plate of the chamber, a low frequency polarized electrode is mounted. In a manner known per se, this electrode serves to generate a plasma when required by polarizing the gas present in the chamber.

At the start of the method covered by the invention, for producing the product of the invention, the pressure in the chamber is brought to 5 mbar using a low vacuum pump. This serves to rid the chamber of the dust and impurities which could deteriorate the physical properties of the surface of the final product.

Helium gas (He) is then introduced into the chamber at a rate of 1 l/min, together with monosilane gas (SiH₄) at a rate of 35 ml/min. At the same time, the substrate is exposed to a plasma obtained using a 100 W power generator for a period of 5 minutes. In this way, the glass or polymethylmethacrylate (PMMA) plaque is coated with a layer of silicon 200 nm thick, hence between 50 nm and 300 nm thick, according to one feature of the invention.

Such a layer could also be added on to this transparent substrate by any other means known to a person skilled in the art. It would also be composed differently provided that a different kind of gas is employed.

The second step of the method consists in generating roughnesses on the outer surface of the layer thereby added on to the substrate. For this purpose, an etching step is carried out on this layer. According to one feature of the invention, this etching step is carried out using a plasma, that is gas ionized by an electromagnetic field. In the example selected here, the gases employed are argon (Ar) and carbon tetrafluoride (CF₄). These gases are introduced into the chamber at the rate of 0.6 l/min and under a pressure of 1 mbar. The power for generating the electromagnetic field is about 100 W for a period of 5 minutes. Alternately, the plasma could be based on oxygen, helium, etc., the role of this plasma being to “attack”, “detach”, or “erode” the atoms of the surface of the intermediate layer in order to structure or texture it, so as to generate the nanoroughnesses.

It is during this nanotexturing or nanostructuring step that the roughnesses having nanometric-size dimensions are formed on the outer surface of the intermediate layer. At the end of this step, the intermediate silicon layer has a thickness of 50 nm, with nanoroughnesses having dimensions of about 20 nm. The nanoroughnesses therefore have “peaks”, “valleys” and intervals between these peaks and valleys smaller than 50 nm in size, according to one feature of the invention.

Since the plasma is distributed isotropically over the whole substrate, the nanoroughnesses are distributed uniformly over the entire outer surface of the intermediate layer. This intermediate layer may also be qualified as “sacrificial” because it losses part of its thickness during this etching step. The thickness in fact decreases from 200 nm to 50 nm.

According to one feature of the method covered by the invention, the third step consists in depositing on the surface of the layer thereby structured a continuous film, of a type suitable for conferring on the coating the desired superhypophilic or superhydrophobic character. In the example selected to illustrate an embodiment of the invention, the desired character is the superhydrophobic character. However, without going beyond the scope of the invention, it may conversely be possible to confer a superhydrophilic character on the product.

To obtain it, a film of siloxane, which is hydrophobic, is produced. For this purpose, a precursor, dimethyltetrasiloxane, is introduced in gaseous form into the chamber under a pressure of 1 mbar and at a rate of 50 ml/min, at the same time as the introduction of the helium gas at a rate of 500 ml/min. This operation is carried out under plasma with a generator set at a power of 200 W for 25 s.

Thus, a continuous film is deposited on the previously structured intermediate layer, a film suitable for making the product hydrophobic. In the example selected, the hydrophobic film is composed of a polysiloxane. Alternately, this film could consist of a compound selected from fluorocarbon polymers.

Conversely, to produce a superhydrophilic product, a hydrophilic compound must be selected to form the film. Hydrophilic films are numerous and have the particular feature of possessing hydrophilic functions without necessarily being soluble in water: they do not absorb water.

Since the film is uniformly deposited on the intermediate layer having nanoroughnesses, the film itself has nanoroughnesses. The cumulative presence of these nanoroughnesses and of this hydrophobic film confer a superhydrophobic character on the final product. Thus, if a drop of water is deposited on the outer surface of the product resulting from the method of the invention, this surface has a contact angle of about 160° with this drop of water, with a hysteresis of about 8°.

In a manner known per se, the contact angle is measured locally. It represents the angle formed in a plane transverse to the surface of the solid (film) by a tangent to the outer envelope of the drop on a line taken in the liquid-solid (drop-film) interface. This line obviously represents an average direction of the surface formed at the liquid-solid interface. Furthermore, the hysteresis represents the deviation between the contact angles at the front and back of a drop when the latter is set in motion.

Water has been taken here as an example, but the product covered by the invention would react similarly with other fluids, such as oils. The surface of the product resulting from the method of the invention therefore also has a lipophobic character. In principle, the hydrophilic surfaces are characterized in that water completely wets the substrate so that the contact angle of a drop of water becomes zero and non-measurable.

The superhydrophobic character is one of the specific surface physical properties in the context of the invention. However, according to one feature of the product of the invention, it could be desired conversely to confer a superhydrophilic character on the product. According to the invention, the film deposited during the third step of the method of the invention may consist of a compound selected from the group comprising silicas, polyvinylpyrydines, polyvinylpyrrolidones, polyols, polyimines, modified polysiloxanes, molecules having a hydroxyl or carboxyl radical. Such compounds are suitable for making the product superhydrophilic, if they are deposited on a nanorough intermediate layer.

The continuous film is deposited here by plasma enhanced chemical vapour deposition. However, according to one feature of the invention, it could be deposited by electronic grafting or by coating (deposition) of a polymer solution. In the case of electronic grafting or electrografting, it is nevertheless necessary to deposit a conducting layer.

Since no step of the method of the invention requires heating to a very high temperature, the present invention has an application for producing a product from any type of substrate, whether heat-sensitive or not. Thus, in the example given above, the substrate may be made from polymethylmethacrylate (PMMA), which has a limit temperature before deformation of about 110° C. This feature of the method according to the invention constitutes an advantage over the prior art methods described above.

Moreover, the method covered by the invention is relatively simple to implement and relatively inexpensive. In fact, the procedure and the equipment required are simplified (a single chamber) and hence, the production costs and times are lower than those of the prior art methods.

The invention also relates to the product produced by the method, hence transparent and having a superhydrophilic or superhydrophobic specific surface physical property. This product comprises a transparent substrate, here made from glass or polymethylmethacrylate (PMMA). This substrate is coated on part of its surface, for example, one of its sides in the case of plaque, with an intermediate structuring layer consisting of monosilane, and then a continuous film deposited on this layer, this film being hydrophilic or hydrophobic. This specific physical property of the product is conferred thereon by the nature of the film and by the nanoroughnesses of the surface of the layer receiving the film. Thus, the product remains transparent and its surface is superhydrophilic or superhydrophobic.

In consequence, when the desired specific surface physical property is superhydrophobicity, the outer surface of such a product has a water-repellent, dirt-repellent capacity. Such a product is thus qualified as self-cleaning and/or anti-condensation. The self-cleaning character of a self-cleaning or dirt-repellent surface is obtained by reducing the contact area between this surface and water, dust, or other pollutants, and also by the hydrophilic character of the continuous film deposited on the surface of the product.

In principle, the pollutants or drops can only be fixed on the “peaks” or apices of the nanoroughnesses of the film, which accordingly form as many obstacles to the dissemination of the pollutants or of the water on the lower surface. The pollutants are then entrained by the drops of water which remain relatively spherical, because they have a high surface energy. Thus, these drops flow very rapidly, under the effect of gravity or aeraulic forces, with a rotational movement that detaches the dust found on the “peaks” of the nanoroughnesses. This is the dirt-repellent or self-cleaning effect.

The applications of the product resulting from the method of the invention are very numerous. They encompass all applications requiring a dirt-repellent or anti-condensation transparent surface. These various applications have been mentioned above.

Furthermore, the product of the invention also has an application for having a sliding surface with respect to fluids, as for key bases or certain aero-or hydrodynamic parts.

1-18. (canceled)

19. A product having superhydrophilic or superhydrophobic surface physical properties, comprising a substrate coated on its surface with a structuring layer added on to said surface and with a film deposited on said layer, wherein the film is continuous, in that the physical properties of said surface are conferred by the nature of the film, and in that the surface of the layer receiving the deposited film has roughnesses smaller than 50 nm.

20. A product having surface physical properties according to claim 19, wherein the combination of the structuring layer and the film is transparent.

21. A product having surface physical properties according to claim 19, wherein said layer comprises hydrogen combined with silicon and/or carbon.

22. A product having surface physical properties according to claim 19, wherein the thickness of the layer is between 50 nm and 300 nm and the spacing between the roughnesses is smaller than 50 nm.

23. A product having surface physical properties according to claim 19, wherein the film consists of a compound selected from the group comprising fluorocarbon polymers, polysiloxanes, in order to make the product superhydrophobic.

24. A product having surface physical properties according to claim 19, wherein the film consists of a compound selected from the group comprising silicas, polyvinylpyiydines, polyvinylpyrrolidones, polyols, polyimines, modified polysiloxanes, molecules having a hydroxyl or carboxyl radical, in order to make the product superhydrophilic.

25. A product having surface physical properties according to claim 19, wherein at least one of its constituent materials, and the substrate in particular, is heat-sensitive.

26. A product having surface physical properties according to claim 19, wherein the substrate consists of glass or polymethylmethacrylate (PMMA).

27. Method for producing a product having superhydrophilic or superhydrophobic surface physical properties, said product comprising a substrate, wherein it consists in succession in:
adding a layer to the outer surface of said substrate;
generating roughnesses of the outer surface of the layer thus added to said substrate;
depositing on the surface of the layer thus structured a continuous film, whereof the nature confers on the coating thereby produced the desired superhydrophilic or superhydrophobic character;
the said roughnesses having dimensions smaller than 50 nm.

28. Method according to claim 27, wherein it is carried out in a plasma enhanced chemical vapour deposition (PECVD) chamber.

29. Method according to claim 27, wherein the coating layer is prepared by vacuum deposition technologies.

30. Method according to claim 27, wherein the roughnesses are generated by plasma etching.

31. Method according to claim 27, wherein the film is deposited by a method selected from the group comprising plasma enhanced chemical vapour deposition, electronic grafting (electrografting) and the deposition of a polymer solution followed by an evaporation of the solvent from the solution.

32. Method according to claim 27, wherein the layer is formed in a thickness of between 50 nm and 300 nm and in that the roughnesses are generated with dimensions smaller than 50 mn.

33. Method according to claim 27, wherein the film consists of a compound selected from the group comprising fluorocarbon polymers, polysiloxanes, in order to make the product superhydrophobic.

34. Method according to claim 27, wherein the film consists of a compound selected from the group comprising silicas, polyvinylpyrydines, polyvinylpyrrolidones, polyols, polyimines, modified polysiloxanes, molecules having a hydroxyl or carboxyl radical, in order to make the product superhydrophilic.

35. Use of a product according to claim 19 for an application requiring a transparent dirt-repellent or anti-condensation surface and selected from the group comprising dirt-repellent home windows, dirt-repellent spectacle lenses, anti-condensation diving masks, dirt-repellent optics of lighting systems such as headlights, automobile or aircraft windows with one moisture-repellent inner side and a self-cleaning outer side, dirt-repellent solar panels, dirt-repellent sensors and measuring instruments such as Pitot tubes or temperature probes, dirt-repellent sanitary surfaces such as those of wash basins, showers, self-cleaning toilets, dirt-repellent surface antennas such as for a radar or satellite television, dirt-repellent decorative metal structures, miscellaneous dirt-repellent industrial surfaces such as those of slaughterhouses, butcher shops, pork butcher shops, hospitals, kitchens, dirt-repellent and anti-condensation aircraft wings, inside walls of fluid containers such as those of anti-condensation bottles for recovering 100% of the content.

36. Use of a product according to claim 19 for an application requiring a transparent and sliding surface with regard to fluids and selected from the group comprising ski bases, aero-or hydrodynamic parts.
